(19) United States
(12) Patent Application Publication
(10) Pub. No.: US 2003/0090340 A1
(43) Pub. Date: May 15, 2003

(54) SIGNAL FILTER

(76) Inventor: Hui-Tang Chen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/986,836

(22) Filed: Nov. 13, 2001

(51) Int. Cl. H03H 7/075

(52) U.S. Cl. 333/185; 333/175

(57) ABSTRACT

A signal filter includes a main circuit board having two opposite sides each having a longitudinal grounding circuit formed on the main circuit board and two opposite ends each having a connector attached to the main circuit board. The connector has a metal portion electrically connecting to the grounding circuit of the main circuit board to promote the grounding effect of the signal filter. A tube is mounted around the two connectors to form a chamber to hold the main circuit board in the tube and prevent water vapor from permeating into the signal filter and damaging electric components in the signal filter.

### BACKGROUND OF THE INVENTION

1. Field of the Invention

The present invention relates to a filter, and more particularly to a signal filter that has an improved grounding circuit.

2. Description of Related Art

To transform and download data from the Internet faster, a cable modem was developed and is now marketed. Two signals, a TV signal and an Internet signal, are transmitted on the cable. However, the two signals have different frequencies and intensities. Sometime the two signals interfere with each other. Signal filters are used to resolve the problem. The types of the signal filters are HPF (High Pass Filter) used for a LPF (Low Pass Filter) used for a computer or a complex one that is used for the TV or the computer, such as BPF (Band Pass Filter) and the BSF (Band Stop Filter). The signal filters have different capabilities and applications based on the specific circuitry. However, the structure and configuration of the individual elements of the signal filters are similar from one type to another.

With reference to FIG. 10, a conventional signal filter comprises multiple filtering elements (50) electrically connected one after one by a wire (52) that has an insulated coating (not shown). The filtering elements (50) at opposite ends of the signal filter have cable connectors (51) integrally extending from the external ends of the filtering elements (50). The cable connector (51) is adapted to connect to a cable that transmits TV or computer signals. Each filtering element (50) has a housing (not numbered) that is made of metal and abuts adjacent housings to form a grounding circuit. To optimize the filtering capability, each filtering element (50) has at least one adjustable capacitor (53) with the adjustment point on an outer periphery of the filtering element (50). The manufacturer adjusts the frequency response of the filtering element (50) during the manufacturing process. A tube (54) is pressed around two connectors (51) with the filtering elements (50) inside the tube (54). An O-ring (511) is mounted between each connector (51) and the tube (54) to prevent water vapor from permeating into the signal filter and damaging the electric components in the signal filter.

A conventional signal filter can prevent TV and the Internet signals from interfering with each other. However, the conventional signal filter has following disadvantages that need to be advantageously altered.

1. The signal transmitting effect is not very good. The grounding circuit is the abutting sections of the filtering element (50) housing. The connection between the filtering elements (50) is weak so that the signal may be lost after passing through the conventional signal filter.

2. The conventional signal filter is hard to manufacture. Each filtering element (50) is individually manufactured prior to assembly of the signal filter and each adjustable capacitor (53) needs to be adjusted during manufacturing, which take a lot of time and raise the manufacturing cost.

The present invention has arisen to mitigate and/or obviate the disadvantages of the conventional signal filter.

### SUMMARY OF THE INVENTION

The main objective of the present invention is to provide a signal filter that has an improved grounding circuit.

To achieve the objective, the signal filter in accordance with the present invention includes a main circuit board having a longitudinal grounding circuit formed opposite sides of the main circuit board and a connector mounted on each end of the main circuit board. The connector has a metal portion electrically connected to the grounding circuit of the main circuit board. A tube is pressed around the two connectors to form a watertight chamber to hold the main circuit board in the tube.

Further benefits and advantages of the present invention will become apparent after a careful reading of the detailed description with appropriate reference to the accompanying drawings.

### BRIEF DESCRIPTION OF THE DRAWINGS

FIG. 1 is a partially exploded perspective view of a signal filter in accordance 1 with the present invention;

FIG. 2 is a top plan view in partial section of the signal filter in FIG. 1 with the tube removed;

FIG. 3 is a bottom plan view in partial section of the signal filter in FIG. 1 with the tube removed;

FIG. 4 is a partially exploded perspective view of another embodiment of a signal filter in accordance with the present invention;

FIG. 5 is a top plan view in partial section of the signal filter in FIG. 4 with the tube removed;

FIG. 6 is a bottom plan view in partial section of the signal filter in FIG. 4 with the tube removed;

FIG. 7 is a plan view in partial section of the signal filter in FIG. 4 with the tube removed;

FIG. 8 is a top plan view in partial section of another embodiment of the signal filter in accordance with the present invention with the tube and electronic components removed;

FIG. 9 is a top plan view in partial section of the signal filter in FIG. 8 with the main circuit board populated; and

FIG. 10 is a partially exploded perspective view of a conventional signal filter in accordance with the prior art.

### DETAILED DESCRIPTION OF THE INVENTION

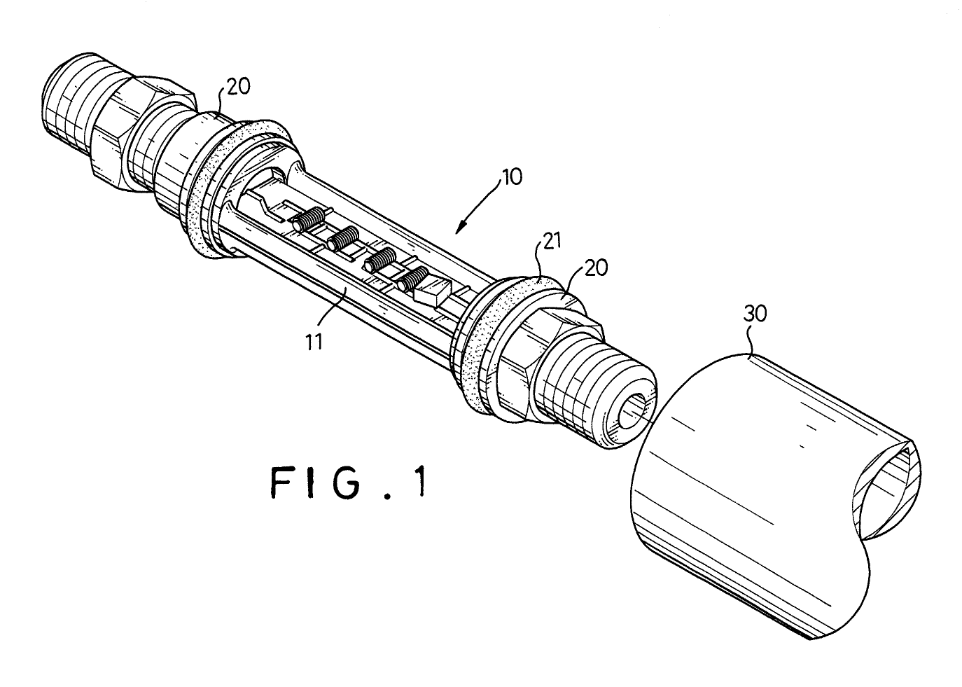

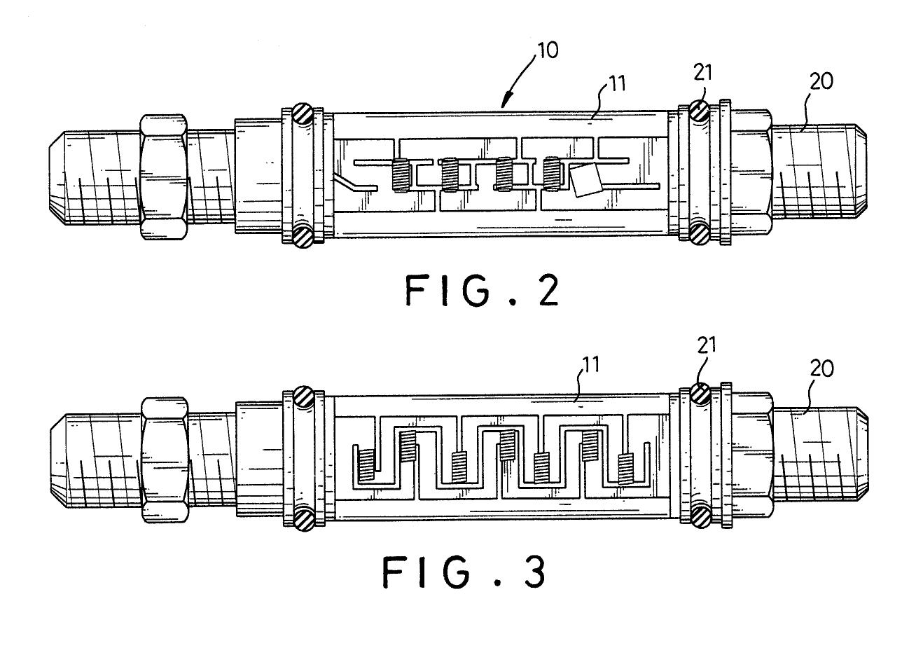

With reference to the drawings and initially to FIGS. 1-3, a signal filter in accordance with the present invention comprises a rectangular main circuit board (10) with filtering function, two connectors (20) and a tube (30). The connectors (20) are mounted on opposite ends of the main circuit board (10). The tube (30) is mounted around the two connectors (20) to form a closed chamber to hold the main circuit board (10) in the tube (30). The signal filter has many electric components that are soldered on the main circuit board (10). However, the arrangement of electric components is not an element of the present invention so further discussion is omitted from the specification.

The rectangular main circuit board (10) includes two opposite sides with a grounding circuit (11) formed on each side to connect the metal portion of the two connectors (20) to provide a good grounding effect. In the preferred embodiment of the present invention, the grounding circuit (11) is soldered to the connector (20) to ensure a solid connection and grounding effect.

The tube (30) is a hollow cylinder so that the main circuit board (10) is mounted inside the tube (30). Each connector (20) includes an outer periphery with an O-ring (21) mounted around the connector (20). The tube (30) is punched to securely press the O-ring (21) and abut the connector (20) so that the signal filter has a double grounding effect. A good grounding effect can effectively promote the performance of the signal filter so that the adjusting step during the manufacturing process is unnecessary with the present invention.

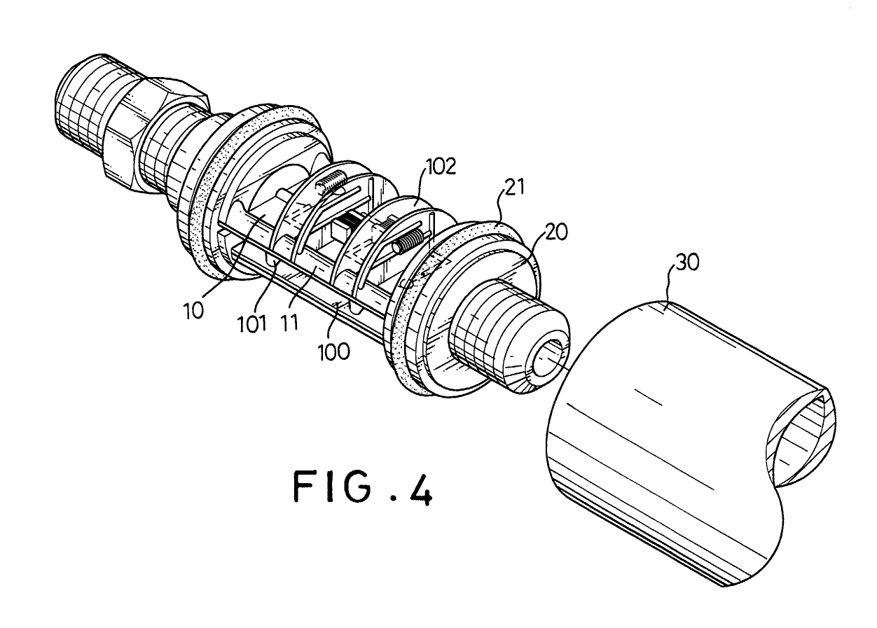

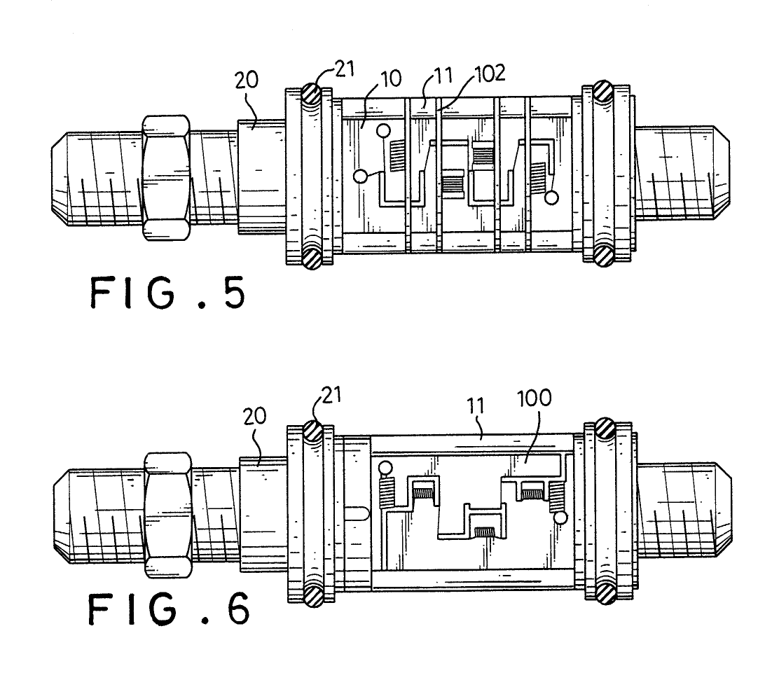

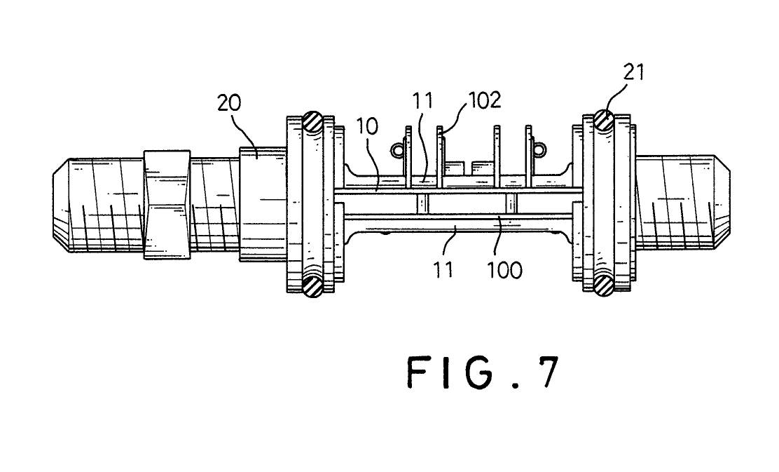

With reference to FIGS. 4-7, another embodiment of a signal filter in accordance with the present invention further comprises a secondary circuit board (100) mounted in the tube (30) parallel to the main circuit board (10). Multiple copper rods (101) connect the grounding circuits of the main circuit board (10) and the secondary circuit board (100). Multiple partitions (102) are perpendicularly attached to the main circuit board (10) to divide any magnetic field caused by the main circuit board (10). Since the filtering effect of the signal filter is adversely effected based on the strength of the magnetic field present, limiting the magnetic field strength to that generated by a subset of the components in the signal filter will improve the overall performance of the filter. The partition (102) includes a first side having a circuit electrically connected to a circuit on the main circuit board (10) and a second side covered with a copper foil (not shown) to electrically connect the two grounding circuits (11) of the main circuit board (10). To conform to the size and shape of the tube (30), the partitions (102) are semi-circular. Because the filter circuitry can be arranged on the partitions (102), this embodiment of the signal filter is more three-dimension so that the volume is smaller than that of the conventional signal filter.

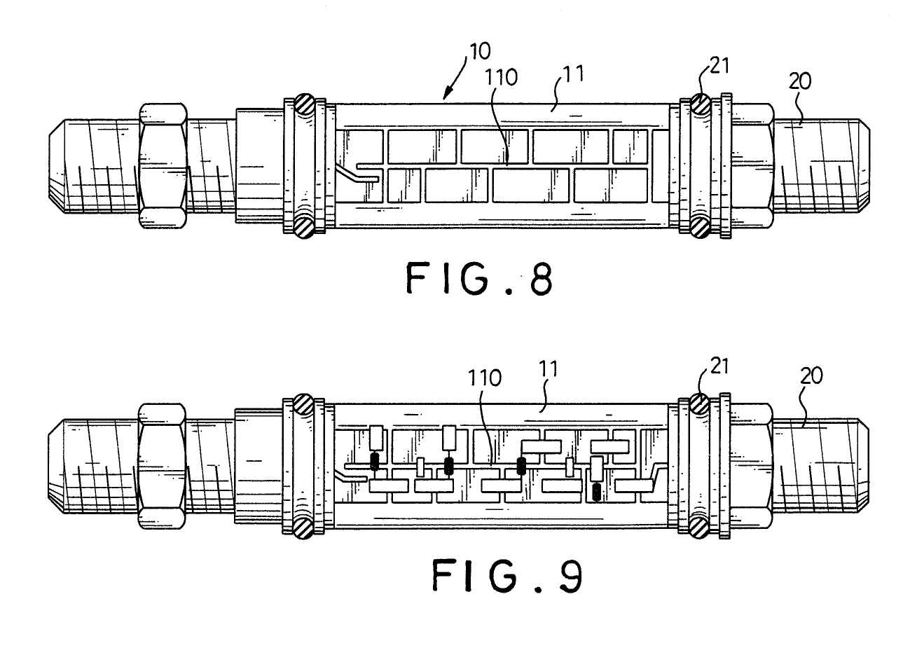

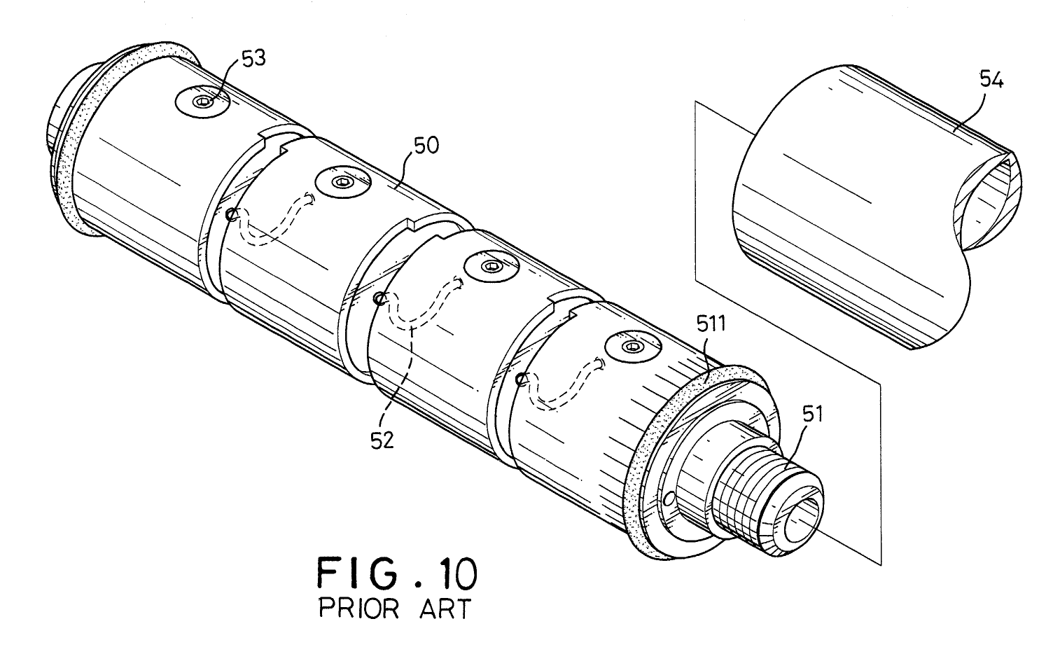

With reference to FIGS. 8 and 9, another embodiment of the circuit (110) is formed on the main circuit board (10) between the two parallel grounding circuits (11) and includes multiple interlocked circuits connecting to the grounding circuits (11) to promote the grounding effect of the signal filter.

As described above, the signal filter in accordance with the present invention has the following advantages.

1. The signal filter is well grounded so the adjusting step during the manufacturing process of the conventional signal filter is unnecessary.

2. The manufacturing time of the present invention is shortened because the adjusting step is unnecessary and the fabrication process for the main circuit board can be automated.

Although the invention has been explained in relation to its preferred embodiment, it is to be understood that many other possible modifications and variations can be made without departing from the spirit and scope of the invention as hereinafter claimed.

What is claimed is:

1. A signal filter comprising:
a main circuit board with filtering function including two opposite sides each having a longitudinal grounding circuit formed on the main circuit board and two opposite ends each having a connector mounted to the main circuit board, the connector having a metal portion electrically connecting to the grounding circuit of the main circuit board; and
a tube mounted around the two connectors to form a closed chamber to hold the main circuit board in the tube.

2. The signal filter as claimed in claim 1, wherein the main circuit board comprises a circuit formed on the main circuit board between the two grounding circuits and including multiple interlocked circuits connecting to the grounding circuits of the main circuit board to promote the grounding effect of the signal filter.

3. The signal filter as claimed in claim 1 further comprising:
a secondary circuit board separately connected to the main circuit board by multiple copper rods and having two opposite sides each having a grounding circuit electrically connecting to a corresponding one of the two grounding circuits of the main circuit board; and
multiple partitions perpendicularly mounted on the main circuit board to divide a magnetic field caused by the main circuit board, each partition including a first side having a circuit electrically connected to a circuit on the main circuit board and a second side having a copper foil attached to electrically connect the two grounding circuits of the main circuit board.

4. The signal filter as claimed in claim 1, wherein the connector comprises an O-ring mounted around the connector to securely abut an inner periphery of the tube to prevent water vapor from permeating into the signal filter and damaging electric components in the signal filter.

5. The signal filter as claimed in claim 2 further comprising:
a secondary circuit board separately attached to the main circuit board by multiple copper rods and having two opposite sides each having a grounding circuit electrically connecting to a corresponding one of the two grounding circuit of the main circuit board; and
multiple partitions perpendicularly mounted on the main circuit board to divide a magnetic field caused by the main circuit board, each partition including a first side having a circuit electrically connected to a circuit on the main circuit board and a second side having a copper foil attached to electrically connect the two grounding circuits of the main circuit board.

6. The signal filter as claimed in claim 2, wherein the connector comprises an O-ring mounted around the connector to securely abut an inner periphery of the tube to prevent water vapor from permeating into the signal filter and damaging electric components in the signal filter.

7. The signal filter as claimed in claim 3, wherein the connector comprises an O-ring mounted around the connector to securely abut an inner periphery of the tube to prevent water vapor from permeating into the signal filter and damaging electric components in the signal filter.

8. The signal filter as claimed in claim 3, wherein the tube is a hollow cylinder and the partition is semi-circular to conform to the tube.

9. The signal filter as claimed in claim 5, wherein the connector comprises an O-ring mounted around the connector to securely abut an inner periphery of the tube to prevent water vapor from permeating into the signal filter and damaging electric components in the signal filter.

10. The signal filter as claimed in claim 5, wherein the tube is a hollow cylinder and the partition is semi-circular to conform to the tube.

11. The signal filter as claimed in claim 7, wherein the tube is a hollow cylinder and the partition is semi-circular to conform to the tube.

12. The signal filter as claimed in claim 9, wherein the tube is a hollow cylinder and the partition is semi-circular to conform to the tube.
